(19) United States
(12) Patent Application Publication
(10) Pub. No.: US 2006/0014381 A1
(43) Pub. Date: Jan. 19, 2006

(54) Method for forming interconnection line in semiconductor device using a phase-shift photo mask

(75) Inventor: Ki Min Lee, Cheongju-si (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/024,741

(22) Filed: Dec. 30, 2004

(30) Foreign Application Priority Data
Jul. 13, 2004 (KR) 2004-54326

(51) Int. Cl. H01L 21/4763

(52) U.S. Cl. 438/638

(57) ABSTRACT

A method for forming a dual damascene structure. The method includes depositing an interlayer dielectric on an underlying layer, depositing a photoresist on the interlayer dielectric, and exposing and developing the photoresist by using a phase-shift photo mask to form a photoresist pattern having trench patterns and hole patterns. The method also includes etching the interlayer dielectric by using the hole patterns of the photoresist pattern, removing the hole patterns of the photoresist pattern, and forming contact and wiring holes having a double-step structure in the interlayer dielectric by etching the interlayer dielectric by use of the trench patterns of the photoresist patterns.

### BACKGROUND OF THE INVENTION

1. Field of the Invention

The present invention relates to a semiconductor manufacturing technology, and more specifically, to a method for forming interconnection lines in a semiconductor device by using a phase shift photo mask.

2. Description of the Related Art

Metallization technology is crucial in IC (Integrated Circuit) devices for interconnection of circuit elements such as transistors, and for paths for power supply and signal transmission.

In conventional IC devices, the metallization wiring material is mainly aluminum. However, decrease of the CD (critical dimension) for higher integration and increased operational speed of semiconductor ICs requires an increase in the wiring resistance and contact resistance. This causes the problem of electromigration, and thus research and development on copper wiring has been widely conducted.

Copper has lower electric resistance of about 62% of the resistance of aluminum. Copper also has superior resistance against electromigration in comparison to aluminum, which enables improved reliability of copper metallization in highly integrated and high speed devices.

Since copper is not dry-etched differently from aluminum, dual damascene processes that form damascene structures having contact and wiring holes included in interlayer dielectrics have to be used for the metallization wiring.

The conventional dual damascene process includes sequential deposition of first and second interlayer dielectrics on a semiconductor substrate, forming wiring holes by etching the second interlayer dielectric by the use of a first photo mask followed by a cleaning process, and forming contact holes that expose the top surface of the substrate by etching the first interlayer dielectric by the use of a second photo mask followed by a cleaning process.

For the conventional dual damascene process, two different photo masks have to be employed, and two photolithographic and etching processes and two cleaning processes are required. Therefore, misalignment of the masks may easily occur, the processing becomes complex, and manufacturing cost increases.

Moreover, when the second interlayer dielectric is etched for the formation of the wiring holes, an etch stop layer made of nitride film should be placed between the first and second interlayer dielectrics to prevent the damage to the first interlayer dielectric from the etchant. This raises the manufacturing cost and makes the damascene process much more complex.

### SUMMARY OF THE INVENTION

The present invention addresses the problems of conventional dual damascene process by implementing the dual damascene structure implemented by a single photo mask.

The present invention decreases the manufacturing cost and simplifies the dual damascene process.

The present invention improves the stability of the manufacturing process and prevents damage to underlying layers in the dual damascene process.

The present invention can be accomplished by using a photo mask that has a hole and a trench of double-step structure. The hole is made of phase shifting material such as MoSi, SiₓO_{y}N_{z} and oxide. The trench is made of opaque metal film. In the phase shift photo mask, a region exposed by the hole is within the region exposed by the trench. The photoresist region exposed to light passing through the hole-exposed region has different properties from the region exposed to light through trench-exposed region. As a result, with a single photo mask, a double-step structure can be implemented using the photoresist. According to another aspect of the present invention, a metallization wiring process includes depositing an interlayer dielectric on an underlying layer, depositing a photoresist on the interlayer dielectric, exposing and developing the photoresist by using a phase-shift photo mask to form a photoresist pattern having trench patterns and hole patterns. The phase-shift photo mask has holes and trenches of double-step structure. The hole is made of phase-shifting material and the trench is made of opaque metal. The process further includes etching the interlayer dielectric by using the hole patterns of the photoresist pattern, removing the hole patterns of the photoresist pattern, and forming contact and wiring holes having a double-step structure in the interlayer dielectric by etching the interlayer dielectric by use of the trench patterns of the photoresist patterns.

In an exemplary embodiment, the step of etching the interlayer dielectric may be performed with an etching selectivity to the photoresist pattern of about 4 to about 7. In this step, a gas mixture of about 50 to about 100 sccm of CF₄, about 50 to about 100 sccm of CHF₃, about 50 to about 150 sccm of O₂ and about 50 to about 500 sccm of Ar may be employed. In the step of removing the hole patterns, a gas mixture of about 50 to about 300 sccm of O₂, about 10 to about 60 sccm of CF₄, and about 100 to about 500 sccm of Ar may be used. In the step of forming contact and wiring holes, a gas mixture of about 0 to about 30 sccm of CHF₃, about 0 to about 50 sccm of O₂, about 0 to about 50 sccm of C₅F₈, and about 300 to about 1000 sccm of Ar, or a gas mixture of about 5 to about 30 sccm of C₄F₈, about 100 to about 800 sccm of CO, about 100 to about 500 sccm of Ar, and about 5 to about 30 sccm of O₂ may be employed. The underlying layer may include a semiconductor substrate, polysilicon layers, and metal wiring layers. When a copper metal layer is used as the underlying layer, SiN may be deposited on the copper metal layer. A SiN layer may be formed as an etch stop layer when forming the wiring holes in the interlayer dielectric.

These and other aspects will become evident by reference to the description of the invention.

It is to be understood that both the foregoing general description of the invention and the following detailed description are exemplary, but are not restrictive of the invention.

### BRIEF DESCRIPTION OF DRAWINGS

The accompanying drawings, which are incorporated in and constitute a part of the specification, illustrate an embodiment of the invention, and, together with the description, serve to explain the principles of the invention:

FIGS. 1A to 1C are perspective views for illustrating the manufacturing process of a photo-mask used in the present invention;

FIG. 2 is a cross sectional view of the photo mask of the present invention;

FIGS. 3A to 3C are cross sectional views for illustrating the processing steps for forming copper metal lines according to an embodiment of the present invention;

FIGS. 4A to 4D are cross sectional views for illustrating the processing steps for forming copper metal lines according to the second embodiment of the present invention; and

FIGS. 5A to 5D are cross sectional views for illustrating the processing steps for forming copper metal lines according to the third embodiment of the present invention.

### DETAILED DESCRIPTION OF THE INVENTION

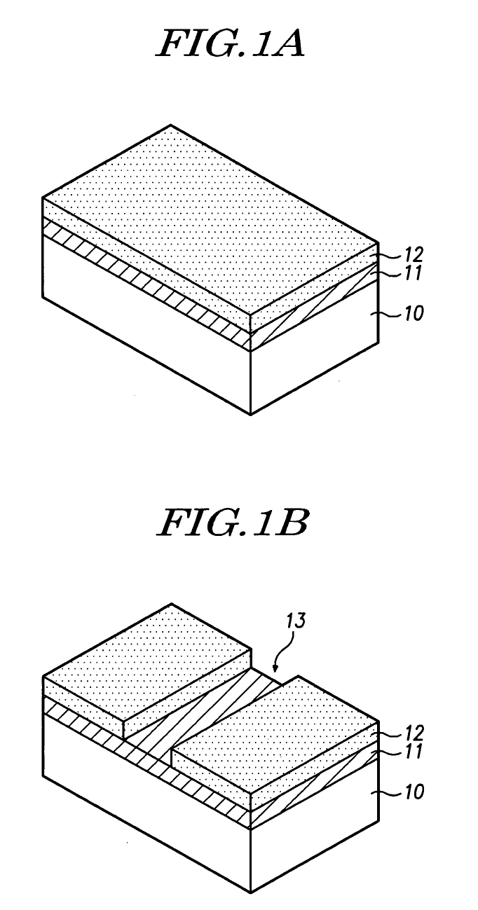

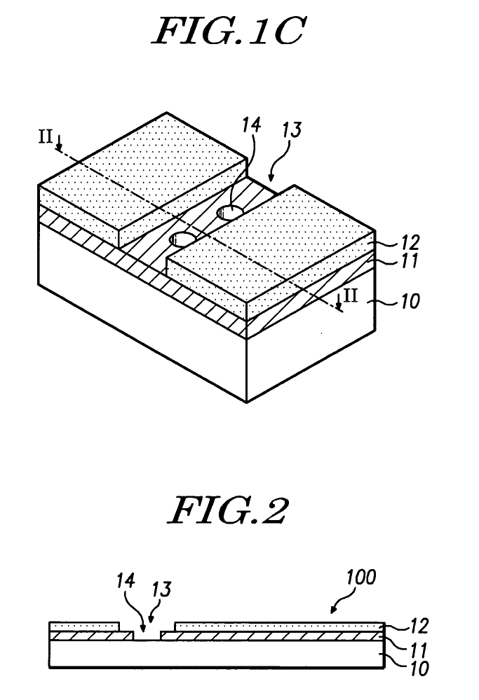

With reference to FIGS. 1 and 2, a manufacturing method for a photo mask suitable for use in the present invention is explained.

Referring to FIG. 1A, PSM (Phase Shift Material) layer 11 having semi-transmittance is formed on a transparent substrate 10. PSM layer 11 is made of, for example, quartz. Opaque metal layer 12 is formed on the PSM layer 11. Opaque metal layer 12 is made of, for example, chromium (Cr). The PSM layer 11 may also be made of a MoSi film, SiₓO_{y}N_{z} film or oxide film. A photo mask that includes the PSM layer 11 is called herein ‘a phase-shift photo mask’ or ‘a phase-shift mask’.

The technology of a photo mask using a PSM is described in e.g., U.S. Pat. No. 5,308,721 (May 4, 1994) entitled “Self-aligned method of making phase-shifting lithographic masks having three or more phase-shifts,” and a dual damascene structure manufactured by using the phase shift mask is described in e.g., U.S. Pat. No. 6,180,512 (Jan. 30, 2000) entitled “Single-mask dual damascene processes by using phase-shifting mask.” The photo mask described in the '512 patent does not employ PSM layers. Rather a phase-shifting region is formed by etching a transparent quartz substrate to a specific depth (200-2,000 Å). By making use of the phase-shifting region, trenches of damascene structure are formed and vertical holes placed at different locations of the photo mask are formed by using the transparent region to implement the dual damascene structure.

Now referring to FIG. 1B, the chrome layer 12 is etched by photolithography to form a trench 13, which exposes a predetermined region of PSM layer 11.

As shown in FIGS. 1C and 2, a portion of the PSM layer 11 exposed by the trench 13 is etched to form a hole 14, which partially exposes the transparent substrate 11. A phase shift photo mask 100 is thus formed. As illustrated in the cross sectional view of FIG. 2, the hole 14 is formed within the trench 13. The hole 14 and trench 13 have a double-step structure. Therefore, light incident on the exposed region of the transparent substrate 10 through the hole 14 propagates through the mask 100 without experiencing any change of its phase, while light incident on the exposed region of PSM layer 11 through the trench 13 changes its phase when passing through the mask 100.

In the above description, the PSM layer 11 is formed first and then the opaque metal layer 12 is formed on the PSM layer 11. However, it is possible to change the stack structure by forming the opaque metal layer 12 first.

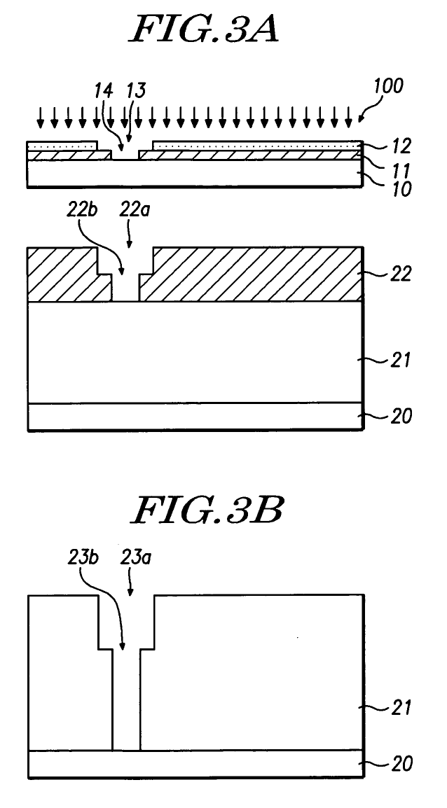

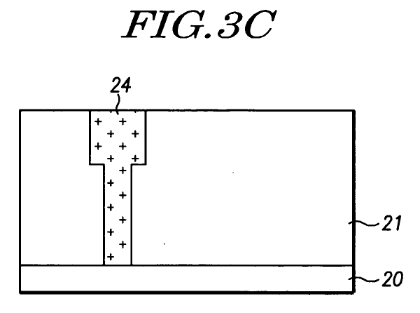

With reference to FIGS. 3A to 3C, a method for forming copper metal lines by using the phase shift photo mask 100 is explained.

Referring to FIG. 3A, an interlayer dielectric 21 is formed on a semiconductor substrate 20. A photoresist 22 is deposited on the interlayer dielectric 21, and the photoresist is exposed by using the phase shift mask 100 prepared as explained above with reference to FIGS. 1 and 2. Since the photo mask 100 has double-step trench 13 and hole 14, the photoresist, upon exposure by the light passing through the mask 100, has different properties in areas where the PSM layer 11 is missing and areas where the PSM layer 11 is present. Thus, after developing the photoresist, the double-step structure of the mask is transferred to the photoresist 22 as shown in FIG. 3A.

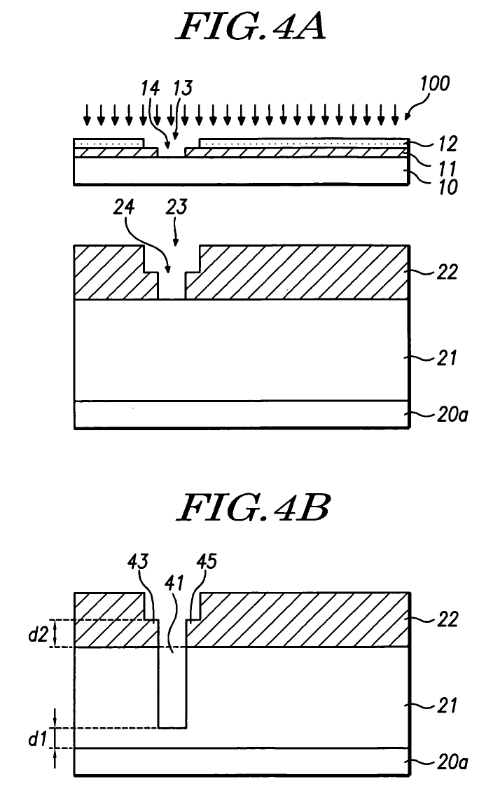

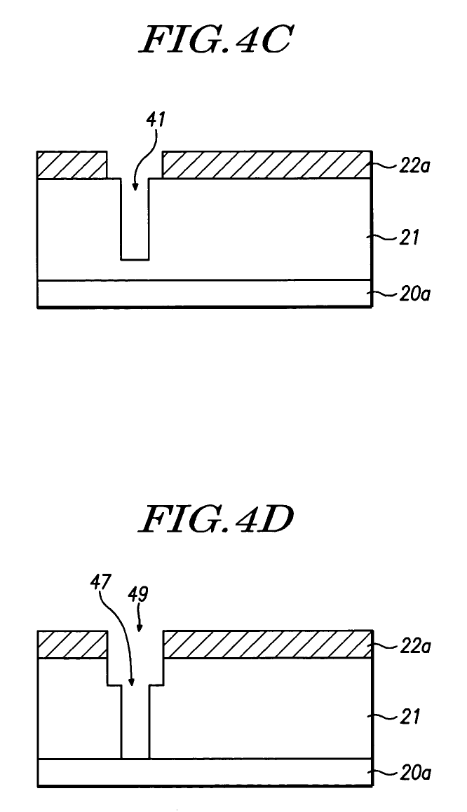

Referring to FIG. 3B, the interlayer dielectric 21 is etched by using the photoresist pattern 22 of double-step structure to form both wiring holes 23a and contact holes 23b, and to form a dual damascene structure 23 (shown in FIG. 4A) that partially exposes the substrate 20. In one embodiment, the etching of the interlayer dielectric 21 is performed with the etching selectivity to the photoresist pattern of about 4 to about 7. The photoresist pattern 22 is removed and the cleaning process is performed by conventional methods. The substrate 20 is exposed by the contact hole 23b. The exposed surface of the substrate 20 is electrically interconnected to copper metal that fills the wiring hole 23a and the contact hole 23b. In this regard, the substrate 20 in FIG. 3 is not limited to semiconductor substrates but may represent any layers (e.g., polysilicon or a lower metal wiring line) to be interconnected to upper metal wiring lines.

Referring to FIG. 3C, a copper film is deposited by, e.g., an electroplating method, on the interlayer dielectric 21 to fill the damascene structure 23. Copper wiring layer 24, contacting the substrate 20, is formed by, e.g., a CMP (Chemical Mechanical Polishing) process.

### Second Embodiment

FIGS. 4A to 4D are cross sectional views illustrating a second embodiment of the present invention.

Like the first embodiment of the present invention, the photoresist formed on the interlayer dielectric 21 is exposed and developed by using the phase shift photo mask 100. The phase shift photomask 100 has the trench and hole patterns 13 and 14 of a double-step structure. Photoresist pattern 22 is formed to have a double-step structured trench and contact patterns 23 and 24 as shown in FIG. 4A. In this embodiment, the underlying layer 20a may be a copper metal layer on which a protection layer such as SiN (not shown) may be formed.

Referring to FIG. 4B, the interlayer dielectric 21 is etched to form a first contact hole 41. The stepped walls 43 and 45 are defined by side walls of the contact hole pattern 24 and a bottom surface of the trench pattern 23. The formation of the first contact hole 41 is performed by using a gas mixture of about 50 to about 100 sccm of CF₄, about 50 to about 100 sccm of CHF₃, about 50 to about 150 sccm of O₂ and about 50 to about 500 sccm Ar. It should be noted that the depth of the first contact hole 41 is about 80% of the thickness of the interlayer dielectric 21. That is, the distance ‘d1’ in FIG. 4B is about 20% of the thickness of the interlayer dielectric 21. This is to prevent attack or damage to the SiN on the copper of the underlying layer 20a. Further, the purpose of the gas mixture of CF₄, CHF₃, O₂ and Ar is to prevent the formation of a fence that may be produced around the contact hole 41 due to excessive amount of polymers generated when the trench is etched in subsequent processes.

After the formation of the first contact hole 41, the stepped walls 43 and 45 are removed as shown in FIG. 4C by using a gas mixture of about 50 to about 300 sccm of O₂, about 10 to about 60 sccm of CF₄, and about 100 to about 500 sccm of Ar. The removal of the stepped walls 43 and 45 can be accomplished by etching the photoresist pattern 22 the thickness denoted ‘d2’ in FIG. 4B. While removing the stepped walls, the interlayer dielectric 21 may be slightly etched, i.e., the bottom surface of the contact hole 41 is etched a little.

Referring to FIG. 4D, by using as a mask the photoresist pattern 22a to which the stepped walls 43 and 45 are removed, the interlayer dielectric 21 is etched to form the contact and wiring holes 47 and 49. For the formation of the contact and wiring holes 47 and 49, a gas mixture of about 0 to about 30 sccm of CHF₃, about 0 to about 50 sccm of O₂, about 0 to about 50 sccm of C₅F₈, and about 300 to about 1000 sccm of Ar, or a gas mixture of about 5 to about 30 sccm of C₄F₈, about 100 to about 800 sccm of CO, about 100 to about 500 sccm of Ar, and about 5 to about 30 sccm of O₂ may be employed. Since these gas mixtures have sufficient etching selectivity with regard to SiN, etching of SiN on copper of the underlying layer 20a can be prevented. In addition, the copper metal of underlying layer 20a is not exposed when the contact hole 47 is etched. Further, no etch stop layers are used to etch the wiring hole 49. Thus, a W-shape generated by over-etching of the corners of the wiring hole 49 during the wiring hole etch can be prevented.

### Third Embodiment

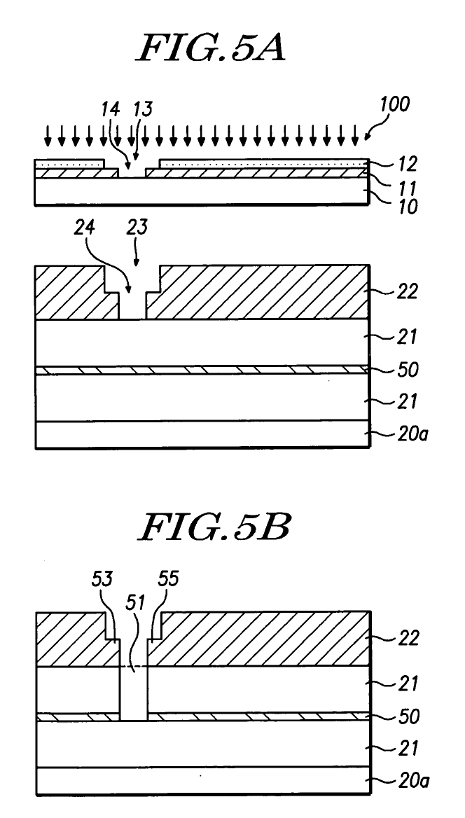

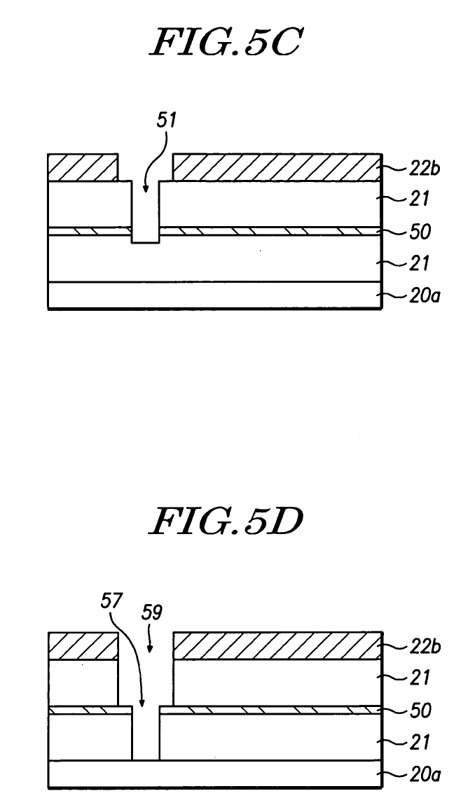

FIGS. 5A to 5D are cross sectional views illustrating the third embodiment of the present invention.

A trench etch stop layer 50 is placed in the interlayer dielectric 21. The trench etch stop layer 50 is, for example, a SiN layer. Different features of the third embodiment will be explained.

Referring to FIG. 5B, the interlayer dielectric 21 is etched to the stop layer 50 using as a mask the stepped walls 53 and 55. This forms the first contact hole 51. As shown in FIG. 5D, the trench etch stop layer 50 remains on the upper surface of the contact hole 57 when the contact and wiring holes 57 and 59 are formed. The processes for the first contact hole 51, photoresist pattern 22b and etching of the contact and wiring holes 57 and 59 are the same as in the second embodiment. The underlying layer 20 in this embodiment may include silicon substrate, polysilicon, and/or copper metal layers.

The process for filling copper metal into the contact and wiring holes and forming a metal wiring layer as explained for the first embodiment can be applied to the second and third embodiments as well.

Korean Patent Application No. 2004-54326, filed on Jul. 13, 2004, is hereby incorporated by reference in its entirety.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method for forming metal wiring of a semiconductor device, comprising the steps of:
preparing a phase shift photo mask having a double-step structured hole and trench, said hole made in a phase shifting material and said trench made in an opaque metal film;
depositing an interlayer dielectric on an underlying layer;
depositing a photoresist on the interlayer dielectric;
exposing and developing the photoresist by using the phase shift photo mask to form a photoresist pattern, the photoresist pattern having a hole pattern corresponding to the hole of the phase shift photo mask and a trench pattern corresponding to the trench of the phase shift photo mask, in the hole and trench patterns having a double-step structure; and
etching the interlayer dielectric by using the photoresist pattern to form a wiring hole and a contact hole of a double-step structure in the interlayer dielectric, said wiring hole corresponding to the trench pattern of the photoresist pattern and said contact hole corresponding to the hole pattern of the photoresist pattern.

2. The method of claim 1, wherein the step of etching the interlayer dielectric includes etching the interlayer dielectric with an etching selectivity of the interlayer dielectric to the photoresist of about 4 to about 7.

3. The method of claim 1, wherein the step of etching the interlayer dielectric further comprises steps of:
etching the interlayer dielectric by using the hole pattern of the photoresist pattern;
removing the hole pattern of the photoresist pattern; and
etching the interlayer dielectric by using the trench pattern of the photoresist pattern.

4. A method for forming metal wiring of a semiconductor device, comprising the steps of:
preparing a phase shift photo mask having a double-step structured hole and trench, said hole made in a phase shifting material and said trench made in an opaque metal film;
depositing an interlayer dielectric on an underlying metal layer;
depositing a photoresist on the interlayer dielectric;
exposing and developing the photoresist by using the phase shift photo mask to form a photoresist pattern, the photoresist pattern having a hole pattern corresponding to the hole of the phase shift photo mask and a trench pattern corresponding to the trench of the phase shift photo mask, the hole and trench patterns having a double-step structure;
etching the interlayer dielectric layer by using the hole pattern of the photoresist pattern to form a first contact hole with a predetermined thickness of the interlayer dielectric unetched;
removing the hole pattern of the photoresist pattern; and
etching the interlayer dielectric by using the trench pattern of the photoresist pattern to form a wiring hole and a contact hole of double-step structure in the interlayer dielectric.

5. The method of claim 4, wherein the step of forming a first contact hole employs a gas mixture of about 50 to about 100 sccm of CF₄, about 50 to about 100 sccm of CHF₃, about 50 to about 150 sccm of O₂ and about 50 to about 500 sccm of Ar.

6. The method of claim 4, wherein the step of removing the hole pattern of the photoresist pattern employs a gas mixture of about 50 to about 300 sccm O₂, about 10 to about 60 sccm of CF₄, and about 100 to about 500 sccm of Ar.

7. The method of claim 4, wherein the step for forming a wiring hole and a contact hole of double-step structure in the interlayer dielectric employs a gas mixture of about 0 to about 30 sccm of CHF₃, about 0 to about 50 sccm of O₂, about 0 to about 50 sccm of C₅F₈, and about 300 to about 1000 sccm of Ar.

8. The method of claim 4, wherein the step for forming a wiring hole and a contact hole of double-step structure in the interlayer dielectric employs a gas mixture of about 5 to about 30 sccm of C₄F₈, about 100 to about 800 sccm of CO, about 100 to about 500 sccm of Ar, and about 5 to about 30 sccm of O₂.

9. The method of claim 4, further comprising a step of depositing a SiN layer on the underlying metal layer.

10. The method of claim 4, the phase shifting material is one selected from a group consisting of a MoSi film, a SiₓO_{y}Nₓ film and an oxide film.

11. The method of claim 4, wherein the step of forming a first contact hole and the step of forming a wiring hole and a contact hole of double-step structure in the interlayer dielectric are performed with an etching selectivity of the interlayer dielectric and the photoresist pattern of about 4 to about 7.

12. A method for forming metal wiring of a semiconductor device, comprising the steps of:
preparing a phase shift photo mask having double-step structured hole and trench, said hole being made of phase shifting material and said trench being made of opaque metal film;
depositing an interlayer dielectric on an underlying layer;
depositing a photoresist on the interlayer dielectric;
exposing and developing the photoresist by using the phase shift photo mask to form a photoresist pattern, which has a hole pattern corresponding to the hole of the phase shift photo mask and a trench pattern corresponding to the trench of the phase shift photo mask, the trench pattern and the hole pattern having a double-step structure;
etching, to a location of an etch stop layer, the interlayer dielectric by using the hole pattern of the photoresist pattern to form a first contact hole;
removing the hole pattern of the photoresist pattern; and
etching the interlayer dielectric by using the trench pattern of the photoresist pattern to form a wiring hole and a contact hole of double-step structure in the interlayer dielectric.

13. The method of claim 12, wherein the etch stop layer is a SiN layer.

14. The method of claim 12, wherein the step of forming a wiring hole and a contact hole of double-step structure in the interlayer dielectric includes etching the interlayer dielectric without etching the etch stop layer on an upper surface of the contact hole.

15. The method of claim 12, wherein the step of forming a first contact hole employs a gas mixture of about 50 to about 100 sccm of CF₄, about 50 to about 100 sccm of CHF₃, about 50 to about 150 sccm of O₂ and about 50 to about 500 sccm of Ar.

16. The method of claim 12, wherein the step of removing the hole pattern of the photoresist pattern employs a gas mixture of about 50 to about 300 sccm of O₂, about 10 to about 60 sccm of CF₄, and about 100 to about 500 sccm of Ar.

17. The method of claim 12, wherein the step of forming a wiring hole and a contact hole of double-step structure in the interlayer dielectric employs a gas mixture of about 0 to about 30 sccm of CHF₃, about 0 to about 50 sccm of O₂, about 0 to about 50 sccm of C₅F₈, and about 300 to about 1000 sccm of Ar.

18. The method of claim 12, wherein the step of forming a wiring hole and a contact hole of double-step structure in the interlayer dielectric employs a gas mixture of about 5 to about 30 sccm of C₄F₈, about 100 to about 800 sccm of CO, about 100 to about 500 sccm of Ar, and about 5 to about 30 sccm of O₂.

19. The method of claim 12, wherein the step of forming a first contact hole and the step of forming a wiring hole and a contact hole of double-step structure in the interlayer dielectric are performed with an etching selectivity of the interlayer dielectric and the photoresist pattern of about 4 to about 7.

20. The method of claim 12, wherein the underlying layer includes a semiconductor substrate, a polysilicon, or an underlying metal layer.
